(19) United States
(12) Patent Application Publication
(10) Pub. No.: US 2023/0011034 A1
(43) Pub. Date: Jan. 12, 2023

(54) FUEL CELL SYSTEM

(71) Applicant: TOYOTA JIDOSHA KABUSHIKI KAISHA, Toyota-shi (JP)

(72) Inventor: Shigetaka HAMADA, Nisshin-shi (JP)

(73) Assignee: TOYOTA JIDOSHA KABUSHIKI KAISHA, Toyota-shi (JP)

(21) Appl. No.: 17/663,539

(22) Filed: May 16, 2022

(30) Foreign Application Priority Data
Jul. 6, 2021 (JP) 2021-111980

(51) Int. Cl. H01M 8/04694; G01R 31/382; H01M 8/0438; H02P 4/00; B60L 58/40

(52) U.S. Cl. CPC H01M 8/04694; G01R 31/382; H01M 8/04425; H02P 4/00; B60L 58/40; H01M 2250/20

(57) ABSTRACT

A fuel cell system mounted on a vehicle includes a fuel cell, a fuel cell control unit having a normal mode and a meeting mode in which quietness is given a higher priority than in the normal mode, as a control mode of the fuel cell, a determining unit configured to determine whether there is a request to switch the control mode to the meeting mode, and a mode switch unit configured to switch the control mode to the meeting mode when the determining unit determines that there is a request to switch the control mode to the meeting mode.

### CROSS-REFERENCE TO RELATED APPLICATION

This application claims priority to Japanese Patent Application No. 2021-111980 filed on Jul. 6, 2021, incorporated herein by reference in its entirety.

### BACKGROUND

### 1. Technical Field

The disclosure relates to a fuel cell system.

### 2. Description of Related Art

In a low-load power generation mode, there is known a fuel cell system that supplies fuel gas at low pressure (see, for example, Japanese Unexamined Patent Application Publication No. 2016-031878 (JP 2016-031878 A)).

In contrast, the inventor has studied to ensure quietness in a vehicle equipped with a fuel cell in consideration of having a meeting or the like (not limited to a meeting, a cram school, studying for entrance examination, or a portable classroom) in the vehicle.

### SUMMARY

However, J P 2016-031878 A has not studied at all to ensure quietness in a vehicle equipped with a fuel cell in consideration of having a meeting or the like in the vehicle.

The disclosure provides a fuel cell system capable of ensuring quietness in a vehicle equipped with a fuel cell in consideration of having a meeting or the like (not limited to a meeting, a cram school, studying for entrance examination, or a portable classroom) in the vehicle.

An aspect of the disclosure provides a fuel cell system mounted on a vehicle. The fuel cell system includes a fuel cell, a fuel cell control unit having a normal mode and a meeting mode in which quietness is given a higher priority than in the normal mode, as a control mode of the fuel cell, a determining unit configured to determine whether there is a request to switch the control mode to the meeting mode, and a mode switch unit configured to switch the control mode to the meeting mode when the determining unit determines that there is a request to switch the control mode to the meeting mode.

With this configuration, quietness is ensured in the vehicle equipped with the fuel cell in consideration of having a meeting or the like (not limited to a meeting, a cram school, studying for entrance examination, or a portable classroom) in the vehicle.

This is achieved by providing the mode switch unit configured to switch the control mode to the meeting mode when the determining unit determines that there is a request to switch the control mode to the meeting mode.

When the control mode has been switched to the meeting mode, the fuel cell control unit may be configured to control at least one of a compressor configured to supply oxidant gas to the fuel cell and an injector configured to supply fuel gas to the fuel cell such that at least one of a rotation speed of the compressor and the number of times the injector is driven reduces as compared to the normal mode.

The determining unit may be configured to determine whether there is a request to switch the control mode to the meeting mode based on user's operation or user information.

The fuel cell system may further include a battery configured to be charged with electric power generated by the fuel cell. The mode switch unit may be configure to switch the control mode to a meeting standby mode before switching the control mode to the meeting mode. When the control mode has been switched to the meeting standby mode, the fuel cell control unit may be configured to control an amount of electric power generated by the fuel cell such that a state of charge (SOC) of the battery increases as compared to the normal mode.

The user information may be schedule information set by a user. When a schedule set by the user has come, the determining unit may be configured to determine that there is a request to switch the control mode to the meeting mode.

The fuel cell system may further include a driving torque control unit configured to control driving torque. When the control mode has been switched to the meeting mode, the driving torque control unit may be configured to control the driving torque such that torque variations reduce as compared to the normal mode.

According to the aspect of the disclosure, it is possible to provide a fuel cell system capable of ensuring quietness in a vehicle equipped with a fuel cell in consideration of having a meeting or the like (not limited to a meeting, a cram school, studying for entrance examination, or a portable classroom) in the vehicle.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a system configuration diagram of a fuel cell system;

FIG. 2 is a functional block diagram of a control unit;

FIG. 3 is a flowchart of a first operation example of the fuel cell system;

FIG. 4 is a flowchart of a second operation example of the fuel cell system; and

FIG. 5 is a flowchart of a third operation example of the fuel cell system.

### DETAILED DESCRIPTION OF EMBODIMENTS

Hereinafter, a fuel cell system 1 (fuel cell system with a meeting mode) according to an embodiment of the disclosure will be described with reference to the accompanying drawings. Like reference numerals denote corresponding components in the drawings, and the description will not be repeated.

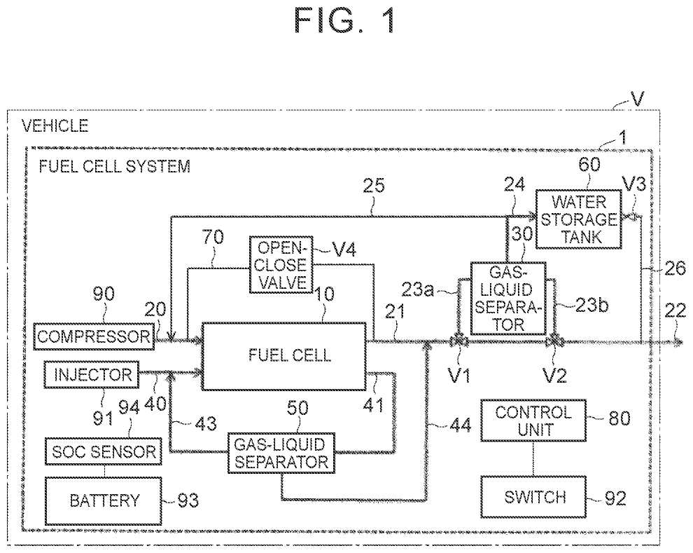

Initially, a configuration example of the fuel cell system 1 according to the embodiment will be described with reference to FIG. 1.

FIG. 1 is a system configuration diagram of the fuel cell system 1.

As shown in FIG. 1, the fuel cell system 1 is a system mounted on a vehicle V. The fuel cell system 1 includes a fuel cell 10, an oxidant gas supply passage 20, a cathode off-gas exhaust passage 21, a gas-liquid separator 30, a fuel gas supply passage 40, an anode off-gas exhaust passage 41, a gas-liquid separator 50, a water storage tank 60, a drain passage 26, a bypass passage 70, a control unit 80, a compressor 90, an injector 91, a switch 92, a battery 93, and the like.

The vehicle V is, for example, a food truck or an office car. A food truck means, for example, a vehicle on which appliances used in a kitchen (for example, cookware) are mounted. An office car means, for example, a vehicle on which appliances used in an office (for example, a display) are mounted. A type of the vehicle V is, for example, a minivan or a camper.

The fuel cell 10 is, for example, a polymer electrolyte fuel cell. The fuel cell 10 includes a stack that is one unit of a plurality of stacked single cells that generate electric power by electrochemical reaction between oxidant gas (air or oxygen) supplied by the compressor 90 via the oxidant gas supply passage 20 and fuel gas (hydrogen) supplied via the injector 91 and the fuel gas supply passage 40. For example, the fuel cell described in Japanese Unexamined Patent Application Publication No. 2018-041630 (JP 2018-041630 A) or Japanese Unexamined Patent Application Publication No. 2019-121578 (JP 2019-121578 A) may be used as the fuel cell 10. Although not shown in the drawing, electric power generated by the fuel cell 10 (stack) is supplied to a drive motor of the vehicle V, various auxiliaries mounted on the vehicle V, and receptacles provided in a vehicle cabin. The receptacles are fittings, to which plugs of electrical appliances (for example, a refrigerator-freezer, a water server, an electric rice cooker, an electric pot, a television, a personal computer, and a charger) are inserted, to obtain electric power (alternating-current power). The receptacles are also called outlets or sockets.

The oxidant gas supply passage 20 is a duct that connects (communicates) the compressor 90 with the fuel cell 10. Oxidant gas (air or oxygen) supplied from the compressor 90 is supplied to the fuel cell 10 via the oxidant gas supply passage 20.

The cathode off-gas exhaust passage 21 is a duct that connects (communicates) the fuel cell 10 with an exhaust port 22. A three-way valve V1 is provided in the cathode off-gas exhaust passage 21 on the side adjacent to the fuel cell 10, and a three-way valve V2 is provided in the cathode off-gas exhaust passage 21 on the side adjacent to the exhaust port 22. The open-closed state of each of the three-way valves V1, V2 is controlled by the control unit 80. Cathode off-gas emitted from the fuel cell 10 is exhausted to outside the vehicle V from the exhaust port 22 via the cathode off-gas exhaust passage 21 in accordance with the open-closed state of each of the three-way valves V1, V2. Cathode off-gas emitted from the fuel cell 10 is supplied to the gas-liquid separator 30 via a connection passage 23a that connects (communicates) the cathode off-gas exhaust passage 21 (three-way valve V1) with the gas-liquid separator 30 in accordance with the open-closed state of the three-way valve V1.

The gas-liquid separator 30 separates oxidant gas and produced water, included in cathode off-gas supplied via the connection passage 23a. The separated oxidant gas is exhausted to outside the vehicle V from the exhaust port 22 via a connection passage 23b that connects (communicates) the gas-liquid separator 30 with the cathode off-gas exhaust passage 21 (three-way valve V2), and the cathode off-gas exhaust passage 21 in accordance with the open-closed state of the three-way valve V2. On the other hand, the separated produced water is supplied to the water storage tank 60 via a produced water supply passage 24 that connects (communicates) the gas-liquid separator 30 with the water storage tank 60 and is stored in the water storage tank 60. Part of the separated produced water is supplied to the oxidant gas supply passage 20 via a circulation passage 25 that connects (communicates) the gas-liquid separator 30 with the oxidant gas supply passage 20 and is used to humidify oxidant gas to be supplied to the fuel cell 10.

The fuel gas supply passage 40 is a duct that connects (communicates) a hydrogen tank (not shown) with the fuel cell 10. Fuel gas (hydrogen) supplied from the hydrogen tank is supplied to the fuel cell 10 via the injector 91 and the fuel gas supply passage 40.

The anode off-gas exhaust passage 41 is a duct that connects (communicates) the fuel cell 10 with the gas-liquid separator 50. Anode off-gas emitted from the fuel cell 10 is supplied to the gas-liquid separator 50 via the anode off-gas exhaust passage 41.

The gas-liquid separator 50 separates fuel gas and produced water, included in anode off-gas supplied via the anode off-gas exhaust passage 41. The separated fuel gas is supplied to the fuel gas supply passage 40 via a circulation passage 43 that connects (communicates) the gas-liquid separator 50 with the fuel gas supply passage 40 and is supplied to the fuel cell 10 again. On the other hand, the separated produced water is supplied to the water storage tank 60 via a produced water supply passage 44 that connects (communicates) the gas-liquid separator 50 with the cathode off-gas exhaust passage 21, and the like, in accordance with the open-closed state of the three-way valve V1 and is stored in the water storage tank 60.

The water storage tank 60 stores the produced water produced in the fuel cell 10. The water storage tank 60 is provided with a drain valve V3. The open-closed state of the drain valve V3 is controlled by the control unit 80. A large amount of produced water is mainly produced while the vehicle V is stopped, and is stored in the water storage tank 60. For example, about one liter of produced water can be stored in the water storage tank 60 after the vehicle has been stopped for one or two hours (depending on the amount of electric power generated).

The drain passage 26 is a duct that connects (communicates) the water storage tank 60 (drain valve V3) with the cathode off-gas exhaust passage 21. The produced water stored in the water storage tank 60 is drained to outside the vehicle V from the exhaust port 22 via the drain passage 26 and the cathode off-gas exhaust passage 21 in accordance with the open-closed state of the drain valve V3.

The bypass passage 70 is a duct that connects (communicates) the oxidant gas supply passage 20 with the cathode off-gas exhaust passage 21. An open-close valve V4 is provided in the bypass passage 70. The open-closed state of the open-close valve V4 is controlled by the control unit 80. Oxidant gas (air or oxygen) supplied from the compressor 90 is supplied to the cathode off-gas exhaust passage 21 via the bypass passage 70 in accordance with the open-closed state of the open-close valve V4, and is further exhausted to outside the vehicle V from the exhaust port 22 via the cathode off-gas exhaust passage 21 in accordance with the open-closed state of each of the three-way valves V1, V2.

The compressor 90 supplies oxidant gas to the fuel cell 10 via the oxidant gas supply passage 20. The rotation speed of the compressor 90 is controlled by a fuel cell control unit 81 (described later).

The injector 91 has an injection port having an on-off valve capable of intermittently injecting hydrogen gas. The number of times the injector 91 is driven (the number of times the on-off valve is turned on or off) is controlled by the fuel cell control unit 81 (described later).

The switch 92 is a switch that is operated by a user and is operated to switch to a normal mode or a meeting mode. The state of the switch 92 is detected by the control unit 80.

The battery 93 is a lead-acid battery that is charged with electric power generated by the fuel cell 10. For example, a secondary battery, such as a nickel-cadmium battery, a nickel-metal hydride battery, and a lithium secondary battery, is suitably used as the battery 93. An SOC sensor 94 is attached to the battery 93. The SOC sensor 94 detects the state of charge (SOC) that is the level of the battery 93.

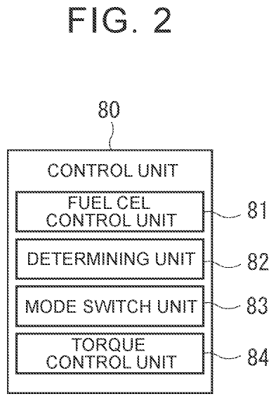

The control unit 80 includes a processor (not shown). The processor is, for example, a central processing unit (CPU). The number of processors may be one or may be multiple. The processor functions as the fuel cell control unit 81, a determining unit 82, a mode switch unit 83, and a torque control unit 84 as shown in FIG. 2 by running a predetermined program loaded from a nonvolatile storage unit (not shown), such as a ROM, onto a RAM (not shown). FIG. 2 is a functional block diagram of the control unit 80. One or some or all of these units may be implemented by hardware.

The fuel cell control unit 81 has a normal mode and a meeting mode in which quietness is given a higher priority than in the normal mode, as a control mode of the fuel cell 10. The fuel cell control unit 81 controls the fuel cell 10 in the control mode set by the mode switch unit 83. For example, when the control mode has been switched to the normal mode, the fuel cell control unit 81 controls the compressor 90 such that the compressor 90 operates at a normal rotation speed. Alternatively, the fuel cell control unit 81 controls the injector 91 such that the number of times the injector 91 is driven is a normal number of times. On the other hand, when the control mode has been switched to the meeting mode, the fuel cell control unit 81 controls at least one of the compressor 90 and the injector 91 such that at least one of the rotation speed of the compressor 90 and the number of times the injector 91 is driven reduces as compared to the normal mode.

The determining unit 82 determines whether there is a request to switch the control mode to the meeting mode. For example, the determining unit 82 determines whether there is a request to switch the control mode to the meeting mode based on user's switch operation or user information. The switch operation is an operation performed on the switch 92 by the user. When the user has operated the switch 92 to switch the control mode to the meeting mode, the determining unit 82 determines that there is a request to switch the control mode to the meeting mode.

The user information is schedule information (for example, meeting start date and time) set by the user. The schedule information is, for example, entered (set) by the user from a mobile terminal (for example, a smartphone) or a stationary information processing terminal (for example, a personal computer) and is acquired by wired or wireless communication between the fuel cell system 1 and the mobile terminal or information processing terminal to which the schedule information is entered. After that, when a schedule (for example, a meeting start date and time) set by the user has come, the determining unit 82 determines that there is a request to switch the control mode to the meeting mode.

The mode switch unit 83 switches the control mode to any one of the normal mode and the meeting mode. For example, when the determining unit 82 determines that there is a request to switch the control mode to the meeting mode, the mode switch unit 83 switches the control mode to the meeting mode.

The torque control unit 84 controls driving torque. Although not shown in the drawing, the driving torque is torque that is transmitted from the drive motor of the vehicle V to drive wheels via a power transmission mechanism and is used to propel the vehicle V. For example, when the control mode has been switched to the meeting mode, the torque control unit 84 controls driving torque such that torque variations reduce (for example, the difference between a torque maximum value and a torque minimum value reduces or the number of times of torque variations per unit time reduces) as compared to the normal mode.

Next, a first operation example of the thus configured fuel cell system 1 will be described.

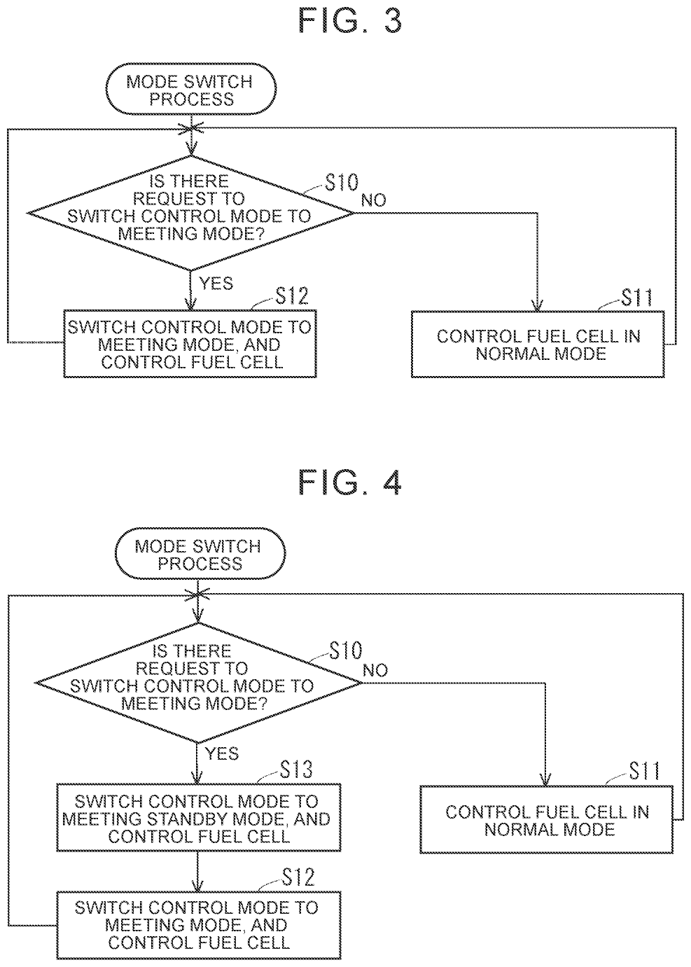

FIG. 3 is a flowchart of the first operation example of the fuel cell system 1.

In the following description, it is assumed that the fuel cell control unit 81 is controlling the fuel cell 10 in the normal mode.

Initially, it is determined whether there is a request to switch the control mode to the meeting mode (step S10). This is determined by the determining unit 82. For example, when the user has operated the switch 92 to switch the control mode to the meeting mode, the determining unit 82 determines that there is a request to switch the control mode to the meeting mode. After that, when a schedule (for example, a meeting start date and time) set by the user has come, the determining unit 82 determines that there is a request to switch the control mode to the meeting mode.

As a result of the determination of step S10, when the determining unit 82 determines that there is no request to switch the control mode to the meeting mode (No in step S10), the fuel cell control unit 81 controls the fuel cell 10 in the normal mode (step S11). For example, the fuel cell control unit 81 controls the compressor 90 such that the compressor 90 operates at a normal rotation speed. Alternatively, the fuel cell control unit 81 controls the injector 91 such that the number of times the injector 91 is driven is a normal number of times.

On the other hand, as a result of the determination of step S10, when the determining unit 82 determines that there is a request to switch the control mode to the meeting mode (Yes in step S10), the mode switch unit 83 switches the control mode to the meeting mode and the fuel cell control unit 81 controls the fuel cell 10 in the set meeting mode (step S12). For example, the fuel cell control unit 81 controls at least one of the compressor 90 and the injector 91 such that at least one of the rotation speed of the compressor 90 and the number of times the injector 91 is driven reduces as compared to the normal mode. Thus, the driving noise of the compressor 90 or the injector 91 is reduced, so a quiet environment suitable for meeting is ensured in the vehicle V equipped with the fuel cell 10. When a schedule (for example, a meeting start date and time) set by the user has come, the control mode automatically switches to the meeting mode, so the convenience of the user improves.

Next, a second operation example of the thus configured fuel cell system 1 will be described.

FIG. 4 is a flowchart of the second operation example of the fuel cell system 1.

FIG. 4 differs from FIG. 3 in that step S13 is added. The remaining configuration is similar to that of FIG. 3. Hereinafter, step S13 that is a difference from FIG. 3 will be mainly described.

As a result of the determination of step S10, when the determining unit 82 determines that there is a request to switch the control mode to the meeting mode (Yes in step S10), the mode switch unit 83 switches the control mode to a meeting standby mode before switching the control mode to the meeting mode, and controls the fuel cell 10 (step S13). When the control mode has been switched to the meeting standby mode, the fuel cell control unit 81 controls the amount of electric power generated by the fuel cell 10 such that the state of charge (SOC) of the battery 93, that is, a detected value of the SOC sensor 94, increases as compared to the normal mode (for example, the amount of charge increases or electric power is charged up to almost upper limit as compared to the normal mode). Thus, it is possible to increase the SOC of the battery 93 before shifting into the meeting mode, so the service time of the battery 93 extends, and the driving of the fuel cell 10 is reduced. When a schedule (for example, a meeting start date and time) set by the user has come, the mode automatically switches to the meeting standby mode, so the convenience of the user improves. The meeting standby mode may be regarded as part of the meeting mode.

For example, when the detected value of the SOC sensor 94 has reached a predetermined value, the process of step S12 is executed. The remaining configuration is similar to the process of FIG. 3.

Next, a third operation example of the thus configured fuel cell system 1 will be described.

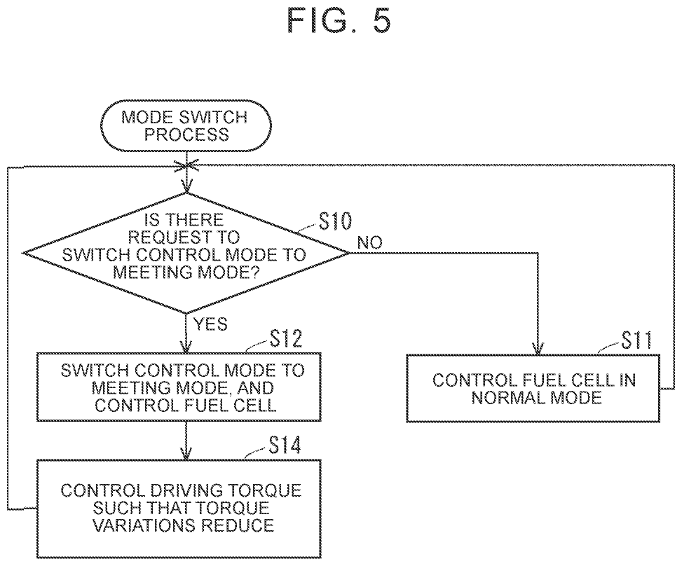

FIG. 5 is a flowchart of the third operation example of the fuel cell system 1.

FIG. 5 differs from FIG. 3 in that step S14 is added. The remaining configuration is similar to that of FIG. 3. Hereinafter, step S14 that is a difference from FIG. 3 will be mainly described.

As a result of the determination of step S10, when the determining unit 82 determines that there is a request to switch the control mode to the meeting mode (Yes in step S10), the mode switch unit 83 switches the control mode to the meeting mode, and the fuel cell control unit 81 controls the fuel cell 10 in the set meeting mode (step S12).

Subsequently, the torque control unit 84 controls driving torque such that torque variations reduce (step S14). For example, the torque control unit 84 controls driving torque such that torque variations reduce (for example, the difference between a torque maximum value and a torque minimum value reduces or the number of times of torque variations per unit time reduces) as compared to the normal mode. Thus, it is possible to have a meeting in a calm situation even in the vehicle V while running. Control over the driving torque may be regarded as part of the meeting mode.

The process of step S14 may be added to FIG. 4.

As described above, according to the embodiment, quietness is ensured in the vehicle V equipped with the fuel cell 10 in consideration of having a meeting or the like (not limited to a meeting, a cram school, studying for entrance examination, or a portable classroom) in the vehicle V.

This is achieved by providing the mode switch unit 83 configured to automatically switch the control mode to the meeting mode when the determining unit 82 determines that there is a request to switch the control mode to the meeting mode (Yes in step S10).

Next, a modification will be described.

The above embodiment has been described above as follows. As a result of the determination of step S10, when the determining unit 82 determines that there is a request to switch the control mode to the meeting mode (Yes in step S10), the fuel cell control unit 81 controls at least one of the compressor 90 and the injector 91 such that at least one of the rotation speed of the compressor 90 and the number of times the injector 91 is driven reduces as compared to the normal mode. However, the configuration is not limited thereto. For example, as a result of the determination of step S10, the determining unit 82 determines that there is a request to switch the control mode to the meeting mode (Yes in step S10), the fuel cell control unit 81 may control the fuel cell 10 such that power generation of the fuel cell 10 is stopped and supply electric power from the battery 93 to the drive motor of the vehicle V, various auxiliaries mounted on the vehicle V, the receptacles provided in the vehicle cabin, and the like.

In the above embodiment, a program includes a command set (or software code) for causing a computer to execute one or more functions described in the embodiment when the program is loaded onto the computer. The program may be stored in a non-transitory computer-readable medium or tangible storage medium. Nonrestrictive examples of the computer-readable medium or tangible storage medium include memory technologies, such as a random-access memory (RAM), a read-only memory (ROM), a flash memory, a solid-state drive (SSD), and others, optical disk storages, such as a CD-ROM, a digital versatile disc (DVD), a Blu-ray (registered trademark) disc, and others, and magnetic storage devices, such as a magnetic cassette, a magnetic tape, a magnetic disk storage, and others. The programs may be transmitted on a transitory computer-readable medium or communication medium. Nonrestrictive examples of the temporary computer-readable medium or communication medium include an electrical, optical, acoustic, or other-type propagation signals.

All the numeric values described in the above embodiment are illustrative and, of course, appropriate numeric values different from those numeric values may be used.

The above embodiment is only illustrative in all respects. The disclosure should not be interpreted restrictively to the above embodiment. The disclosure may be implemented in other various forms without departing from the spirit or main features thereof

What is claimed is:

1. A fuel cell system mounted on a vehicle, the fuel cell system comprising:
a fuel cell;
a fuel cell control unit having a normal mode and a meeting mode in which quietness is given a higher priority than in the normal mode, as a control mode of the fuel cell;
a determining unit configured to determine whether there is a request to switch the control mode to the meeting mode; and
a mode switch unit configured to switch the control mode to the meeting mode when the determining unit determines that there is a request to switch the control mode to the meeting mode.

2. The fuel cell system according to claim 1, wherein, when the control mode has been switched to the meeting mode, the fuel cell control unit is configured to control at least one of a compressor configured to supply oxidant gas to the fuel cell and an injector configured to supply fuel gas to the fuel cell such that at least one of a rotation speed of the compressor and the number of times the injector is driven reduces as compared to the normal mode.

3. The fuel cell system according to claim 1, wherein the determining unit is configured to determine whether there is a request to switch the control mode to the meeting mode based on user's switch operation or user information.

4. The fuel cell system according to claim 1, further comprising a battery configured to be charged with electric power generated by the fuel cell, wherein:
the mode switch unit is configured to switch the control mode to a meeting standby mode before switching the control mode to the meeting mode; and
when the control mode has been switched to the meeting standby mode, the fuel cell control unit is configured to control an amount of electric power generated by the fuel cell such that a state of charge of the battery increases as compared to the normal mode.

5. The fuel cell system according to claim 1, wherein:
the user information is schedule information set by a user; and
when a schedule set by the user has come, the determining unit is configured to determine that there is a request to switch the control mode to the meeting mode.

6. The fuel cell system according to claim 1, further comprising a driving torque control unit configured to control driving torque, wherein, when the control mode has been switched to the meeting mode, the driving torque control unit is configured to control the driving torque such that torque variations reduce as compared to the normal mode.
